(19) United States
(12) Patent Application Publication
(10) Pub. No.: US 2008/0142812 A1
(43) Pub. Date: Jun. 19, 2008

(54) LED and method for marking the same

(75) Inventors: Hsiao-Kuo Chang, Taoyuan City (TW); Chih-Peng Chen, Taipei City (TW); Chih-Wei Hsu, Lujhu Township (TW)

Correspondence Address: BACON & THOMAS, PLLC, 625 SLATERS LANE, FOURTH FLOOR, ALEXANDRIA, VA, 22314, US

(73) Assignee: Kinik Company, Taipei (TW)

(21) Appl. No.: 11/984,136

(22) Filed: Nov. 14, 2007

(30) Foreign Application Priority Data
Dec. 15, 2006 (TW) 095147087

(51) Int. Cl. H01L 33/00

(52) U.S. Cl. 257/77; 438/47; 257/E33.014

(57) ABSTRACT

A light emitting diode device and a method for manufacturing the same are disclosed. The method comprises following steps: (A) providing a substrate; (B) forming a SiC film on the surface of the substrate; (C) forming a diamond layer on the surface of the SiC film and removing the substrate, wherein the diamond layer has a first surface and a second surface adjacent to the surface of the SiC film; (D) forming a semiconductor epitaxy layer on the surface of SiC film by epitaxial growth process; and (E) forming a first electrode on the surface of the semiconductor epitaxy layer and forming a metal layer on the first surface of the diamond layer. Accordingly, the manufacturing method of the present invention can efficiently reduce manufacturing cost and simplify manufacturing process to provide LEDs with high heat dissipation efficiency and a high-quality epitaxy layer.

### BACKGROUND OF THE INVENTION

1. Field of the Invention

The present invention relates to a light emitting diode device and the manufacturing method thereof and, more particularly, to a manufacturing method that can reduce manufacturing cost and simplify manufacturing process, and a light emitting diode device provided by the manufacturing method.

2. Description of Related Art

The light emitting diode device (LED) has been commercialized and applied since the 1960s. Owing to their high resistance to impact, long lifetime, and low power consumption, the LEDs are widely applied in many electrical devices in our daily life, such as in indicating signs and light sources.

In recent years, owing to the rapid development of color variety and high brightness of modern LEDs, the application of LEDs is extended to the outdoor application, e.g. outdoor displays and traffic signals. However, the blue light LEDs improved very slowly until Nichia Inc. disclosed blue/white light LEDs made of GaN in 1993. The blue light LED of GaN is now made of forming a poly-crystal AlN thin film or a single-crystal AlN thin film (functioning as a buffer layer) on the sapphire wafer, and growing gallium nitride (GaN) on the buffer layer in sequence. Since the GaN grown on the buffer layer illustrated above has very good quality, the efficiency and the stability of the light emission can be significantly improved.

However, heat dissipation is still a big problem in the application of the LEDs. If the heat generated from the LEDs cannot be suitably dissipated, the junction temperature of the LEDs will increase that results in the decreasing of the brightness and the lifetime of LEDs. Hence, the reduction of the heat accumulation is still an important subject for the application of LEDs in the field of backlight modules and display devices.

To improve the heat dissipation of the LED, replacement of the material, or that of the structure of the LED in the manufacturing process is required. So far, replacements of the material of the substrate, or flip-chip mounting instead of naked chip mounting are the main ways for improving the heat dissipation of LEDs. Among these methods for improving heat dissipation, some researchers suggested using diamond to replace the sapphire substrate because the high thermal conductivity of diamond may increase the efficiency of heat dissipation of the LEDs. However, even though the lattice matching of the diamond and the gallium nitride is superior to that of the gallium nitride and the sapphire substrate, it is difficult to grow a single crystal gallium nitride layer on the surface of diamond. So far, the difficulty has been reduced somewhat by forming a buffer layer on the surface of the diamond.

In the published US Patent 2005/0164482A1 of Cree Inc., Saxler disclosed a method for forming a high-power, high frequency device in wide band-gap semiconductor materials with reduced junction temperature, higher power density during operation, and improved reliability at a rated power density. The device made of the same method is also disclosed. The method includes steps of adding a layer of diamond to a silicon carbide (SiC) wafer to increase the thermal conductivity of the resulting composite wafer; thereafter reducing the thickness of the silicon carbide portion of the composite wafer by ion implantation while retaining sufficient thickness of silicon carbide to support epitaxial growth thereon; preparing the silicon carbide surface of the composite wafer for epitaxial growth thereon, and adding a Group III nitride heterostructure to the prepared silicon carbide face of the wafer.

FIGS. 1A to 1E show the cross-section views of an LED having a SiC layer as a substrate, and a diamond layer with high heat conductivity as a heat dissipation layer for enhancing heat dissipation efficiency. As shown in FIG. 1A, a SiC substrate 11 is first provided. Then, as shown in FIG. 1B, a diamond layer 12 is formed on the surface of the SiC substrate 11 to function as a heat dissipation layer of an LED. Subsequently, as shown in FIG. 1C, part of the SiC substrate 11 is removed to provide an epitaxial buffer layer of an LED. However, it is difficult to perform the process for removing part of the SiC substrate due to high hardness of the SiC substrate. The process for removing part of the SiC substrate is a choke point in a conventional method. As shown in FIG. 1D, a semiconductor epitaxy layer 13 is formed on the surface of the SiC substrate 11. The semiconductor epitaxy layer 13 includes a first semiconductor layer 131, an active layer 132, and a second semiconductor layer 133 in sequence. Finally, as shown in FIG. 1E, a first electrode 14 and a metal layer 15 are formed on the surfaces of the second semiconductor layer 133 of the semiconductor epitaxy layer 13 and the diamond layer 12, respectively. Herein, the metal layer 15 functions as a second electrode as well as a reflector.

As illustrated above, the manufacturing of the vertical LED (as shown in FIG. 1E) can be completed. A diamond layer with high heat conductivity is applied as a heat dissipation layer in the conventional LED to increase heat dissipation efficiency. A SiC substrate 11 is applied between the diamond layer 12 and the semiconductor epitaxy layer 13 to function as an epitaxial buffer layer to overcome the difficulty of growing an epitaxy layer on the diamond layer 12. However, in the aforementioned process, a SiC substrate with enough thickness for growing an epitaxy layer thereon is necessary, and thereby the manufacturing cost increased due to high cost of the SiC material. Furthermore, the process for removing part of the SiC substrate increased the difficulty of the removing process due to high hardness of the SiC. Therefore, there is an unfulfilled need for a method of reducing manufacturing cost and simplifying the process for manufacturing LEDs with high performance and stability.

### SUMMARY OF THE INVENTION

The object of the present invention is to provide a vertical light emitting diode device and a method for manufacturing the same. The method for manufacturing a vertical light emitting diode device comprises the following steps: (A) providing a substrate; (B) forming a SiC film on the surface of the substrate; (C) forming a diamond layer on the surface of the SiC film and removing the substrate, wherein the diamond layer has a first surface and a second surface adjacent to the surface of the SiC film; (D) forming a semiconductor epitaxy layer on the surface of the SiC film by epitaxial growth process, wherein the semiconductor epitaxy layer comprises a first semiconductor layer, an active layer, and a second semiconductor layer; and (E) forming a first electrode on the surface of the semiconductor epitaxy layer and forming a metal layer on the first surface of the diamond layer.

Accordingly, the method of the present invention is performed by depositing a SiC film and a diamond layer on a substrate of silicon crystal and then removing the substrate of silicon crystal. The aforementioned method performs the easy process for removing the silicon substrate instead of the difficult process for removing part of a SiC layer in a conventional method. In addition, a high-quality SiC film is formed on a low-cost silicon substrate by a deposition in the present invention so as to improve the disadvantage of high cost caused by the utilization of a thick single-crystal silicon substrate for epitaxial growth.

Furthermore, the LED provided by the method of the present embodiment can effectively enhance the efficiency of heat dissipation owing to the diamond layer with high thermal conductivity so as to enhance the performance and stability of products. Besides, in the present invention, a SiC film acts as an epitaxial buffer layer of an LED so that the difficulty of growing an epitaxy layer on a diamond layer is efficiently overcome so as to provide a high-quality product. In addition, the LED of the present invention uses a metal layer as a reflector so as to enhance light extraction and improve the luminescence efficiency of products.

Thereby, the method for manufacturing a vertical LED provided by the present invention can efficiently simplify process, reduce cost and provide an LED with high performance and stability.

The method of the present invention can further comprise a step (Dl) after step (D) and before step (E), forming an ohmic electrode on the surface of the semiconductor epitaxy layer. Herein, the first electrode is formed on the surface of the ohmic electrode.

Besides, the present invention further provides a preferable embodiment to accomplish a lateral LED. The method for manufacturing a lateral LED can be performed by the aforementioned steps (A) to (E) and the diamond layer can be conductive or insulative. The method can further comprise a step (F) after step (E), removing part of the second semiconductor layer and part of the active layer to expose the first semiconductor layer therebelow, and forming a second electrode on the surface of the first semiconductor layer to accomplish a lateral LED. In the lateral LED, the metal layer on the surface of the diamond layer can be a reflector.

Alternatively, the lateral LED also can be accomplished by performing steps (A) to (E); subsequently, removing part of the second semiconductor layer and part of the active layer to expose the first semiconductor layer therebelow; and forming a first electrode and a second electrode on the surfaces of the semiconductor epitaxy layer and the first semiconductor layer, respectively.

In the manufacturing method of the present invention, the process for forming the SiC film in step (B) and the process for forming the diamond layer can be performed by chemical vapor deposition (e.g. Hot-filament Chemical Vapor Deposition, Microwave Assisted Chemical Vapor Deposition, or other equivalent methods), or physical vapor deposition (e.g. Cathodic Arc Evaporation, Ion-Beam Sputtering, Evaporation, Laser Ablation, DC Sputtering, or other equivalent methods).

In the manufacturing method of the present invention, the process for removing the substrate in step (C) and the process for removing part of the second semiconductor layer and part of the active layer can be performed by etching (e.g. wet etching, inductively coupled plasma etch (or reactive ion etch), or dry etching) or grinding (e.g. physical cutting, chemical cutting, or other equivalent methods).

In the manufacturing method of the present invention, the process for forming the semiconductor epitaxy layer in step (D) can be performed by metal organic chemical vapor deposition, molecular beam epitaxy, liquid phase epitaxy, vapor phase epitaxy, or other equivalent methods.

In the manufacturing method of the present invention, the process for forming the metal layer and the first electrode in step (E) and the process for forming the second electrode in step (F) can be performed by physical deposition (e.g. thermal evaporation, electronic beam assisted evaporation, ion-beam sputtering, plasma sputtering, or other equivalent methods), or chemical deposition.

The substrate used in the present invention can be a silicon crystal substrate or other equivalent substrates. In the semiconductor epitaxy layer, the electrical property of the first semiconductor layer is different from that of the second semiconductor layer, and the first semiconductor layer and the second semiconductor layer are made of binary (e.g. AlN or GaN), ternary (e.g. AlGaN or InGaN) or quaternary (e.g. AlInGaN) doping semiconductor. In detail, the first semiconductor layer is an N-type doping semiconductor layer, while the second semiconductor layer is a P-type doping semiconductor layer; and the first semiconductor layer is a P-type doping semiconductor layer, while the second semiconductor layer is an N-type doping semiconductor layer.

The material of the diamond layer of the present invention can be selected from the group consisting of diamond, diamond-like carbon and nano diamond. Herein, the diamond layer can be a conductive or insulative single-crystal diamond film, poly-crystal diamond film, or amorphous diamond film. The material of the diamond layer used in a vertical LED is a conductive diamond, and that used in a lateral LED can be a conductive diamond or an insulative diamond. In addition, the SiC film can be a conductive or insulative single-crystal SiC film.

The materials of the first electrode, the second electrode, and the metal layer used in the present invention are not limited but can be selected from the group consisting of Al, W, Cr, Cu, Ti, Sn, Ni, Mo, Pt, Au, Ag, Be alloy, Ge alloy, Sn alloy, TiN, Al alloy and Cr alloy. In addition, the material of the ohmic electrode used in the present invention can be selected from the group consisting of indium tin oxide, nickel/gold, tin oxide, nickel/gold oxide, magnesium oxide and indium oxide.

In the vertical LED using the conductive diamond layer, the metal layer can be an electrode as well as a reflector. In the lateral LED, the material of the diamond layer can be a conductive diamond or insulative diamond. The metal layer on the surface of the diamond layer can be a reflector and the electrode property is not necessary for the metal layer.

The lateral LED of the present invention can be disposed on a substrate by flip-chip technology. Herein, gold or solder bumps are used between the LED and the substrate for connection so as to form a flip-chip LED.

Accordingly, the present invention uses single-crystal silicon substrate as a substrate for depositing a thin SiC film thereon so as to omit the difficult process for removing part of SiC in a conventional method and reduce cost. In addition, a diamond layer and a SiC film with an ordered crystal array are formed on the surface of the substrate owing to the utilization of a single-crystal silicon substrate as the substrate so as to provide a high-quality LED.

Other objects, advantages, and novel features of the invention will become more apparent from the following detailed description when taken in conjunction with the accompanying drawings.

### BRIEF DESCRIPTION OF THE DRAWINGS

FIGS. 1A to 1E show cross-section views for manufacturing a conventional LED;

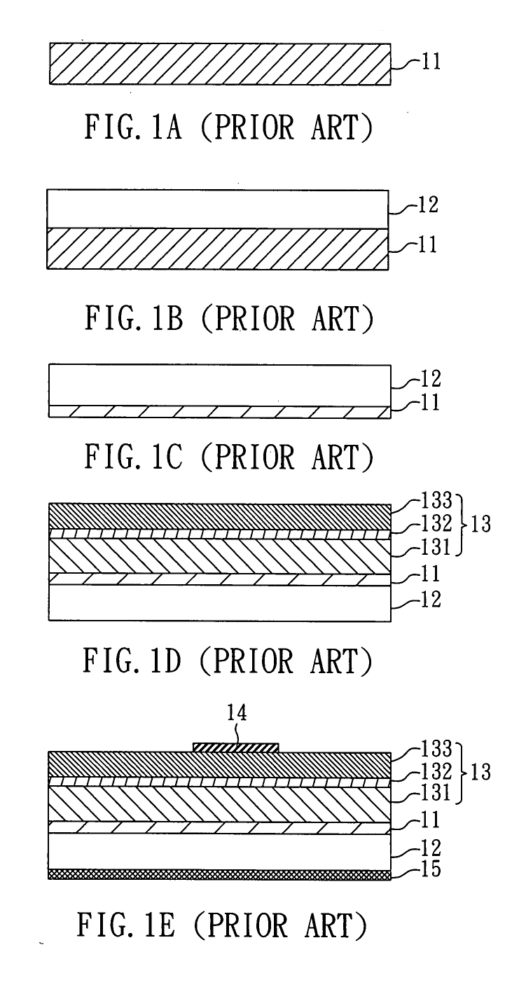

FIGS. 2A to 2G show cross-section views for manufacturing a vertical LED of a preferred embodiment of the present invention; and

FIGS. 3A to 3G show cross-section views for manufacturing a lateral LED of another preferred embodiment of the present invention.

### DETAILED DESCRIPTION OF THE PREFERRED EMBODIMENT

### Embodiment 1

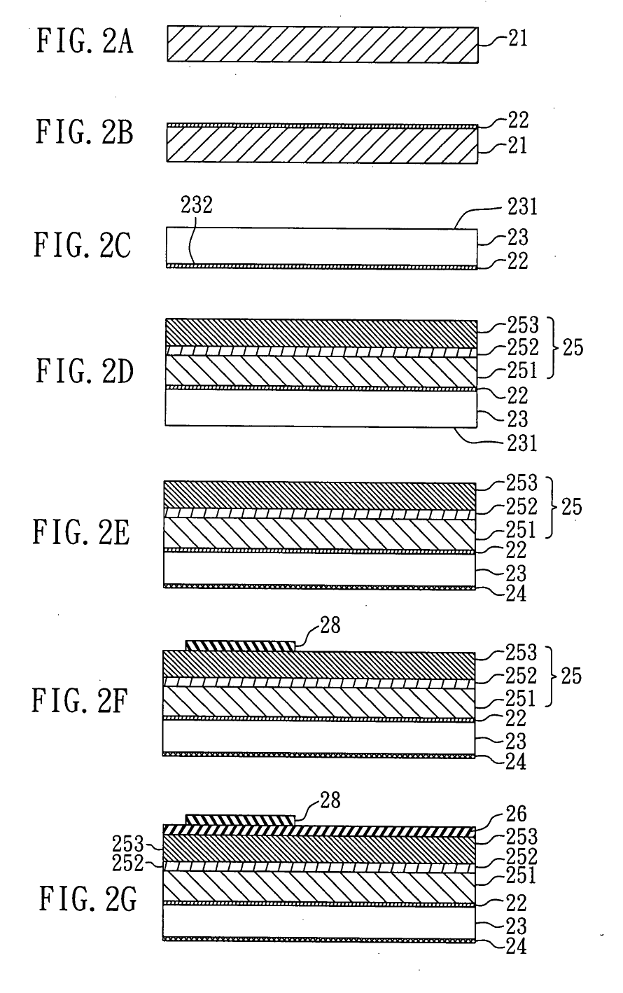

With reference to FIGS. 2A to 2G, a process is shown for manufacturing a vertical LED of a preferred embodiment of the present invention.

As shown in FIG. 2A, a substrate 21 is first provided. In the present embodiment, the substrate 21 is a single-crystal silicon substrate to function as a carrier for depositing a high-quality film. Then, as shown in FIG. 2B, a SiC film 22 is formed on the surface of the substrate 21 by chemical vapor deposition to function as an epitaxial buffer layer of the LED. Herein, the SiC film 22 of the present embodiment is a conductive single-crystal SiC film. Subsequently, as shown in FIG. 2C, a diamond layer 23 is formed on the surface of the SiC film by chemical vapor deposition, and the substrate is removed. Herein, the diamond layer has a first surface 231 and a second surface 232 adjacent to the surface of the SiC film 22. In the present embodiment, the diamond layer 23 is a conductive diamond layer, and the process for removing the substrate is performed by etching.

As shown in FIG. 2D, a semiconductor epitaxy layer 25 is formed on the surface of the SiC film 22 by metal organic chemical vapor deposition (MOCVD). Herein, the semiconductor epitaxy layer 25 comprises a first semiconductor layer 251, an active layer 252, and a second semiconductor layer 253.

Subsequently, as shown in FIG. 2E, a metal layer 24 is formed on the first surface 231 (with reference to FIG. 2D) of the diamond layer 23 by sputtering. Finally, as shown in FIG. 2F, a first electrode 28 is formed on the surface of the second semiconductor layer 253 of the semiconductor epitaxy layer 25 by sputtering so as to accomplish a vertical LED.

Alternatively, after the process as FIG. 2E is performed, a vertical LED also can be accomplished, as shown in FIG. 2G, by sputtering an ohmic electrode 26 on the surface of the second semiconductor layer 253 of the semiconductor epitaxy layer 25 and then forming a first electrode 28 on the surface of the ohmic electrode 26 by sputtering. Accordingly, in the present invention, the first electrode 28 can be formed direct on the surface of the second semiconductor layer 253, or a transparent ohmic electrode 26 is formed on the surface of the second semiconductor layer 253 at first and then the first electrode 28 is formed on the surface of the ohmic layer 26.

In the present embodiment, the material of the metal layer 24 is gold to function as an electrode as well as a reflector so as to enhance light extraction and improve the luminescence efficiency of products.

Accordingly, a SiC film 22 and a diamond layer 23 is deposited on a substrate 21 of silicon crystal in sequence and then the substrate 21 of silicon crystal is removed so that the present embodiment can omit the difficult process for removing part of a SiC layer in a conventional method. In addition, a high-quality SiC film 22 is formed on the substrate 21 of silicon crystal in the present embodiment so as to overcome the disadvantage of high cost caused by the utilization of a thick single-crystal silicon substrate for epitaxial growth.

Furthermore, the vertical LED provided by the method of the present embodiment can efficiently enhance the efficiency of heat dissipation owing to the diamond layer 23 with high thermal conductivity so as to enhance the performance and stability of products. The present embodiment takes a SiC film 22 as an epitaxial buffer layer of an LED so that the difficulty of growing an epitaxy layer on a diamond layer 23 is effectively overcome so as to provide a high-quality product. Besides, the vertical LED of the present embodiment uses a metal layer 24 as an electrode as well as a reflector so as to enhance light extraction and improve the luminescence efficiency of products.

### Embodiment 2

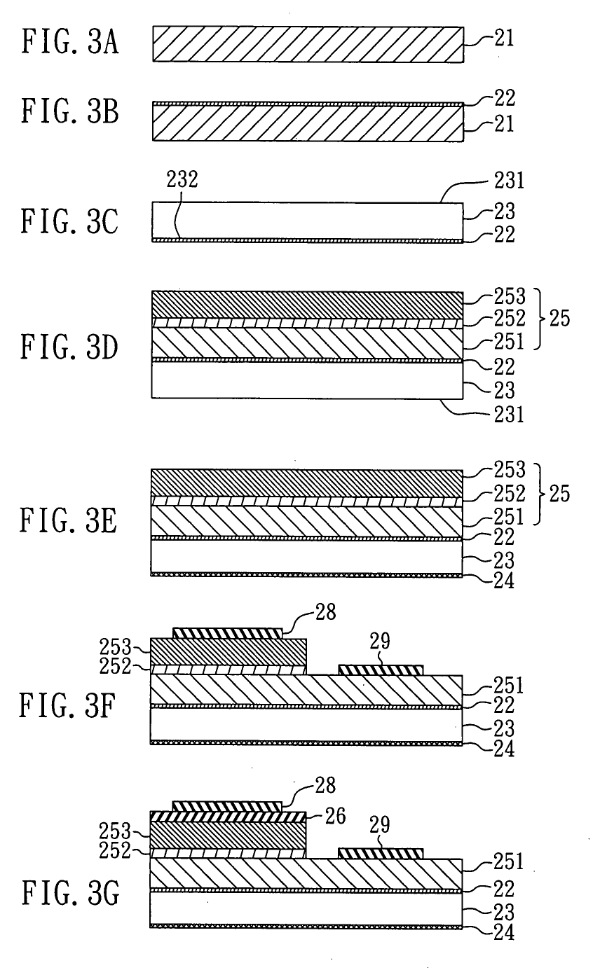

With reference to FIGS. 3A to 3G, a process is shown for manufacturing a lateral LED of another preferred embodiment of the present invention.

The process shown in FIGS. 3A to 3E of the present embodiment is the same as that of FIGS. 2A to 2E of Embodiment 1 except that the materials of the SiC film 22 and the diamond layer 23 used in the present embodiment are insulative. In addition, the present embodiment further comprises the final step for forming a second electrode 29.

After the process as shown in FIGS. 3A to 3E is performed, in reference to FIG. 3F, part of the second semiconductor layer 253 and part of the active layer 252 are removed to expose the first semiconductor layer 251 therebelow by etching. Then, a first electrode 28 and a second electrode 29 are formed on the surfaces of the second semiconductor layer 253 and the first semiconductor layer 251 of the semiconductor epitaxy layer 25 by sputtering, respectively, so as to accomplish a lateral LED. In the present embodiment, the metal layer 24 can be as a reflector.

Alternatively, after the process as FIG. 3E is performed, a lateral LED also can be accomplished, as shown in FIG. 3G, by sputtering an ohmic electrode 26 on the surface of the second semiconductor layer 253 of the semiconductor epitaxy layer 25; then removing part of the ohmic electrode 26, part of the second semiconductor layer 253 and part of the active layer 252 by etching to expose the first semiconductor layer 251 therebelow; and sputtering a first electrode 25 and a second electrode 29 on the surfaces of the ohmic electrode 26 and the first semiconductor layer 251, respectively. Accordingly, in the present invention, the first electrode 28 can be formed directly on the surface of the second semiconductor layer 253, or an ohmic electrode 26 is formed on the surface of the second semiconductor layer 253 at first and then the first electrode 28 is formed on the surface of the ohmic layer 26.

The lateral LED of the present embodiment also exhibits the properties illustrated in Embodiment 1 that is the lateral LED can omit the difficult process for removing part of a SiC layer in a conventional method and overcome the disadvantage of high cost caused by the utilization of a thick single-crystal silicon substrate for epitaxial growth in a conventional method. In addition, as per properties illustrated in Embodiment 1, the lateral LED of the present embodiment can enhance the efficiency of heat dissipation, increase light extraction, and improve the luminescence efficiency, performance and stability of products.

Although the present invention has been explained in relation to its preferred embodiment, it is to be understood that many other possible modifications and variations can be made without departing from the scope of the invention as hereinafter claimed.

What is claimed is:

1. A method for manufacturing a light emitting diode device, comprising steps:
(A) providing a substrate;
(B) forming a SiC film on a surface of the substrate;
(C) forming a diamond layer on a surface of the SiC film and removing the substrate, wherein the diamond layer has a first surface and a second surface adjacent to the surface of the SiC film;
(D) forming a semiconductor epitaxy layer on the surface of the SiC film by epitaxial growth process, wherein the semiconductor epitaxy layer comprises a first semiconductor layer, an active layer, and a second semiconductor layer; and
(E) forming a first electrode on the surface of the semiconductor epitaxy layer and forming a metal layer on the first surface of the diamond layer.

2. The method as claimed in claim 1, wherein the material of the diamond layer is a conductive diamond.

3. The method as claimed in claim 1, wherein in step (E), an ohmic electrode is formed on the surface of the semiconductor epitaxy layer, and then the first electrode is formed on the surface of the ohmic electrode.

4. The method as claimed in claim 1, further comprising a step (F) after step (E), removing part of the second semiconductor layer and part of the active layer to expose the first semiconductor layer therebelow, and forming a second electrode on the surface of the first semiconductor layer.

5. The method as claimed in claim 1, wherein in step (E), part of the second semiconductor layer and part of the active layer are removed to expose the first semiconductor layer therebelow and then the first electrode and a second electrode are formed on the surfaces of the semiconductor epitaxy layer and the first semiconductor layer, respectively.

6. The method as claimed in claim 4, wherein the diamond layer is an insulative diamond layer, or a conductive diamond layer.

7. The method as claimed in claim 1, wherein the electrical property of the first semiconductor layer is different from that of the second semiconductor layer.

8. The method as claimed in claim 1, wherein the substrate is a single-crystal silicon substrate.

9. The method as claimed in claim 1, wherein the SiC film is a single-crystal SiC film, a conductive SiC film, or an insulative SiC film.

10. The method as claimed in claim 1, wherein the SiC film is a conductive SiC film, or an insulative SiC film.

11. The method as claimed in claim 1, wherein the diamond layer is selected from the group consisting of a single-crystal diamond film, a poly-crystal diamond film, and an amorphous diamond film.

12. The method as claimed in claim 1, wherein the process for forming the SiC film in step (B) is performed by physical deposition, or chemical vapor deposition.

13. The method as claimed in claim 1, wherein the process for forming the diamond layer in step (C) is performed by physical deposition, or chemical vapor deposition.

14. The method as claimed in claim 1, wherein the process for removing the substrate in step (C) is performed by wet etching, inductively coupled plasma etch, reactive ion etch, or grinding.

15. A light emitting diode device, comprising:
a diamond layer;
a SiC film disposed on the diamond layer;
a semiconductor epitaxy layer disposed on the SiC film;
a first electrode disposed on the semiconductor epitaxy layer; and
a metal layer disposed under the diamond layer.

16. The light emitting diode device as claimed in claim 15, further comprising an ohmic electrode disposed between the semiconductor epitaxy layer and the first electrode.

17. The light emitting diode device as in claimed 15, wherein the SiC film is a single-crystal SiC film, a conductive SiC film, or an insulative SiC film.

18. A light emitting diode device, comprising:
a diamond layer;
a SiC film disposed on the diamond layer;
a semiconductor epitaxy layer having a first semiconductor layer, an active layer and a second semiconductor layer sequentially dispoded on the SiC film, wherein the first semiconductor layer is partially exposed;
a first electrode and a second electrode disposed on the second semiconductor layer and the exposed first semiconductor layer respectively; and
a metal layer disposed under the diamond layer.

19. The light emitting diode device as in claimed 18, further comprising an ohmic electrode disposed between the first electrode and the second semiconductor layer.

20. The light emitting diode device as in claimed 18, wherein the SiC film is a single-crystal SiC film, a conductive SiC film, or an insulative SiC film.
